(19) United States
(12) Patent Application Publication
(10) Pub. No.: US 2007/0247944 A1
(43) Pub. Date: Oct. 25, 2007

(54) Integrated Semiconductor Memory with Refreshing of Memory Cells

(75) Inventors: Frank Fischer, Munchen (DE); Manfred Proll, Dorfen (DE); Thilo Schaffroth, Rohromoos (DE); Stephan Schroder, Munchen (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/739,444

(22) Filed: Apr. 24, 2007

(30) Foreign Application Priority Data
Apr. 24, 2006 (DE) 102006018921.3

(51) Int. Cl. G11C 11/34; G11C 7/04; G11C 7/00

(52) U.S. Cl. 365/212; 365/222

(57) ABSTRACT

An integrated semiconductor memory with refreshing of memory cells includes a temperature sensor to detect a chip temperature of the integrated semiconductor memory, a connection to apply a command signal, a frequency generation unit to generate a frequency signal, and a memory cell to store a data item, the stored data item being refreshed at the frequency of the frequency signal. The frequency generation unit generates the frequency signal at a first frequency on the basis of a chip temperature detected by the temperature sensor when a first state of the command signal is applied and the frequency generation unit generates the frequency signal at a second frequency, which is changed in comparison with the first frequency, at the same chip temperature when a second state of the command signal is applied.

### CROSS REFERENCE TO RELATED APPLICATIONS

This application claims priority under 35 U.S.C. §119 to Application No. DE 102006018921.3 filed on Apr. 24, 2006, entitled “Integrated Semiconductor Memory with Refreshing of Memory Cells,” the entire contents of which are hereby incorporated by reference.

### BACKGROUND

Certain types of semiconductor memory devices require periodic refreshing of memory cells to retain the data stored in the memory cells. To ensure proper functioning during normal operation, it is desirable to test the refresh operation of such semiconductor memory devices under conditions that will reveal flaws or the potential to malfunction.

### SUMMARY

An integrated semiconductor memory with refreshing of memory cells comprises a temperature sensor to detect a chip temperature of the integrated semiconductor memory, a connection to apply a command signal, a frequency generation unit to generate a frequency signal, and a memory cell to store a data item, the stored data item being refreshed at the frequency of the frequency signal. The frequency generation unit generates the frequency signal at a first frequency on the basis of a chip temperature detected by the temperature sensor when a first state of the command signal is applied and the frequency generation unit generates the frequency signal at a second frequency, which is changed in comparison with the first frequency, at the same chip temperature when a second state of the command signal is applied.

### BRIEF DESCRIPTION OF THE DRAWINGS

The invention will be explained in detail below with reference to figures which show exemplary embodiments of the present invention.

FIG. 1 shows an integrated semiconductor memory with refreshing of memory cells, FIG. 2 shows a first embodiment of a circuit for setting refresh intervals for refreshing memory cells.

FIG. 3 shows a second embodiment of a circuit for setting refresh intervals for refreshing memory cells.

FIG. 4 shows a first dependence of refresh intervals/refresh frequencies on a chip temperature of the semiconductor memory.

FIG. 5 shows a second dependence of refresh intervals/refresh frequencies on a chip temperature of the integrated semiconductor memory.

### DETAILED DESCRIPTION

An integrated semiconductor memory, for example a DRAM (Dynamic Random Access) semiconductor memory, has memory cells which are arranged along word lines and bit lines in a memory cell array. In this case, a DRAM memory cell comprises a selection transistor and a storage capacitor. In order to read a memory cell, a control voltage which turns on the selection transistor of the memory cell to be read is fed to the word line that is connected to the memory cell. As a result, the storage capacitor is conductively connected to the bit line. Charge equalization then occurs between the storage capacitor and the bit line, the charge of the cell being divided between the cell capacitance and the bit line capacitance during the charge equalization. This results in the bit line voltage being displaced in accordance with the ratio of the two capacitances (transfer ratio). The signal swing which is established on the bit line is compared with a constant voltage on a reference bit line and is then amplified by a sense amplifier which is arranged at the end of the bit line.

The storage capacitor of a memory cell in a dynamic memory device comprises two highly conductive layers which have as large an area as possible and are separated by a thin, high-impedance dielectric. When technologically implementing minimal structures on a memory chip, it is not possible to avoid the existence of a multiplicity of high-impedance leakage current paths to the cell surroundings or via the dielectric of the cell. The high-impedance leakage current paths which are strongly dependent on the temperature may result in the charge which is stored in the storage capacitor being discharged and thus in the data of the memory cell being lost. In order to ensure that the correct data contents of a memory cell can be read, a residual charge in the storage capacitor of a memory cell must not be undershot. To this end, the data contents of a memory cell or the sufficient residual charge of a cell must be recharged repeatedly within a defined period of time.

Memory devices are generally operated in different operating modes. The so-called self-refresh mode of memory devices is used, in particular in laptop applications, to save power. If an application on a computer is in the standby mode, the memory modules on the motherboard of a computer are changed to a so-called sleep mode. In this deactivated operating state, no commands or addresses are forwarded from a controller device to the memory device. In the deactivated operating state of the memory device, charge retention within the memory cells is ensured using chip-internal refresh commands. The intervals between the refresh commands guarantee a sufficient charge in the memory cells, with the result that the stored data can be correctly read from the memory cells again during a memory access.

If the periods of time between the internal refresh commands are selected to be very short, the risk of losing data is reduced. On the other hand, however, the power consumption of the semiconductor memory during the power-saving mode increases. If, in contrast, the intervals between the internal refresh commands are selected to be long, the power consumption of the semiconductor memory is reduced but the risk of losing data is increased since the memory contents of the memory cells are refreshed at very long intervals. Therefore, an attempt is made to safeguard charge retention with the smallest possible power consumption when refreshing the memory cells.

Since charge retention in the memory cells is dependent on the temperature, the refresh intervals are matched to the chip temperature of the semiconductor memory. The refresh intervals are thus lengthened at low temperatures at which the charge is generally retained in the memory cells for a relatively long period of time, whereas the refresh intervals are shortened at high temperatures at which the cell charge decreases more rapidly. The power consumption of a semiconductor memory can thus be reduced at least at low chip temperatures.

In order to test the functionality of a semiconductor memory with regard to the refreshing of memory contents in the self-refresh mode, the semiconductor memory is operated in an active operating state in which read and write accesses to memory cells of the integrated semiconductor memory are carried out. In this case, data with data values are read into the memory cells of the semiconductor memory. The semiconductor memory is then operated in the self-refresh mode in which the stored data is refreshed at particular intervals of time. The refresh frequency is internally generated by the semiconductor memory itself in this case. After a certain operating time in the self-refresh mode, the semiconductor memory is changed over to the active operating state again. In the active operating state, the data contents are read from the memory cells and are compared with the data values which were previously written in. Devices which fail during such a test may have either excessively long internal refresh intervals or cells which are weak in terms of charge retention, so-called retention-weak cells, or else a combination of the two phenomena.

Testing of an integrated semiconductor memory in the self-refresh operating state is effective only when crossers of devices do not fail in a customer application as a result of suitable test biases. Instead, it is desirable for such marginally functional devices to be able to be identified as early as during testing by the manufacturer. This is currently not possible when testing in the self-refresh mode since the refresh intervals in the self-refresh mode cannot be modified when testing the integrated semiconductor memory. The intervals tested are exactly the same intervals at which the semiconductor memory will be refreshed during subsequent operation by a customer. Since, during subsequent use, the memory devices are operated in the self-refresh mode for a considerably longer period of time than can be tested by a manufacturer during a test, there is a risk of devices which are marginally functional in the test failing only during subsequent operation by a customer.

If the internal refresh intervals in a semiconductor memory device are not selected by the memory module to be dependent on the temperature, a test bias can be set for the highest and lowest temperatures of the operating temperatures specified in the data sheet using corresponding temperature biases. If, in contrast, the internal refresh intervals are generated by the memory device in a manner dependent on the temperature, as is generally customary in semiconductor memories, critical combinations of internal refresh rates and retention-weak cells may result in the self-refresh mode at any desired temperatures. A test bias in the self-refresh mode can consequently no longer be achieved using a temperature bias. Since the refresh intervals are matched to the changing chip temperatures, the general functionality of a semiconductor memory in the self-refresh mode cannot be guaranteed by testing the semiconductor memory at a test temperature which is above or below the temperatures specified in the data sheet. Test biases are not possible even when testing the self-refresh mode at any desired temperatures within the specified temperature range when refresh intervals are selected to be dependent on the temperature. In contrast, the internally generated refresh intervals at a particular chip temperature correspond exactly to the same values as occur during subsequent operation in a customer's application.

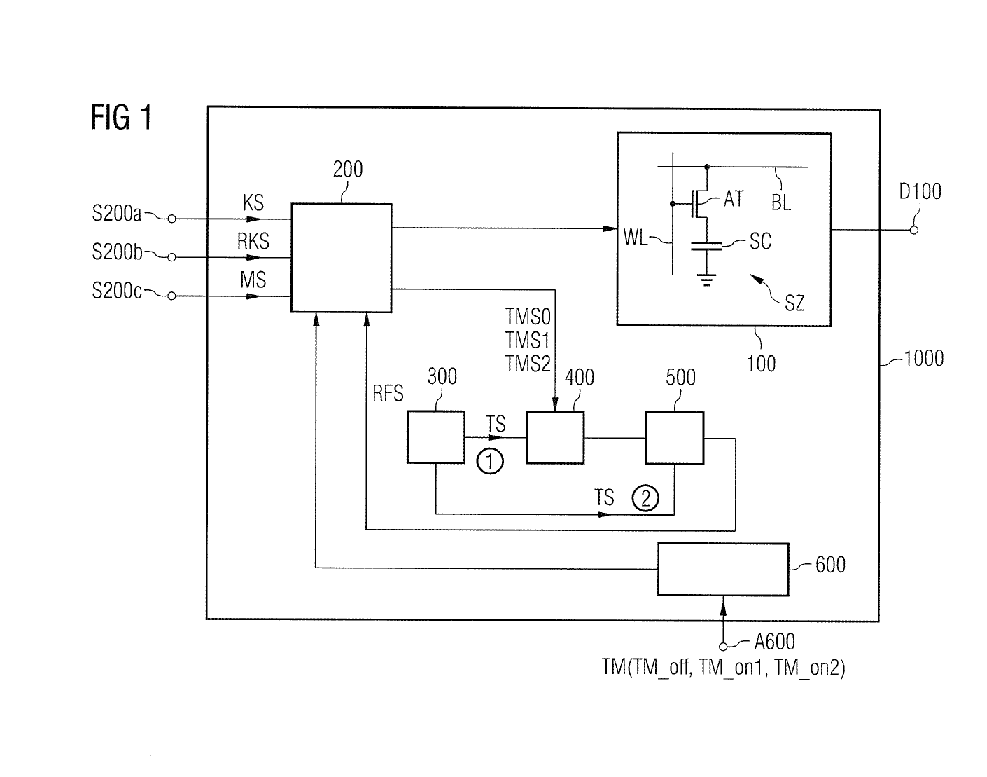

FIG. 1 shows one embodiment of an integrated semiconductor memory 1000 in which the memory contents of memory cells are refreshed at regular intervals. The integrated semiconductor memory 1000 comprises a memory cell array 100 in which memory cells SZ are arranged along word lines WL and bit lines BL. A memory cell SZ is, for example, in the form of a DRAM memory cell which comprises a storage capacitor SC and a selection transistor AT. A corresponding control potential on the word line WL can be used to conductively connect the storage capacitor SC of the illustrated memory cell SZ to the bit line BL. Data can then be stored in the storage capacitor in the form of a charge or the data item stored in the memory cell can be read out.

A control unit 200 which is connected to the memory cell array 100 is provided for the purpose of driving the memory cell array 100 in order to carry out read and write accesses. In order to carry out the read and write accesses, a command signal KS with a corresponding state is applied to a control connection S200a. An address register 600 having an address connection A600 for applying address signals is provided for the purpose of selecting a memory cell for the read or write access. In order to refresh the memory contents of the memory cells, a command signal RKS is applied to a control connection S200b of the control circuit 200 in an active operating state of the integrated semiconductor memory. Read and write accesses to the memory cells of the semiconductor memory can be carried out in the active operating state. A refresh operation within the memory cell array takes place, for example, each time the state of the command signal RKS changes. In contrast to the active operating state, a self-refresh mode of the memory takes place in the standby mode (sleep mode). In this case, the refresh commands are internally generated in the memory chip of the semiconductor memory. To this end, a frequency generation unit 500 provides a frequency signal RFS which indicates a refresh frequency. The frequency signal RFS is a periodic signal which is supplied to the control unit 200 which refreshes the memory cells of the memory cell array SZ in the self-refresh mode in accordance with the frequency of the frequency signal.

Provision is also made of a temperature sensor circuit 300 which determines a chip temperature of the integrated semiconductor memory. It generates, at the output, a temperature evaluation signal TS which, in a first embodiment of the integrated semiconductor memory, is supplied to the input of a control circuit 400 and, in a second embodiment of the integrated semiconductor memory, is supplied to the input of the frequency generation unit 500. The control circuit 400 is also driven by test mode control signals TMS0, TMS1 or TMS2. The states of the test mode control signals are generated by the control unit 200 on the basis of the states TM_off, TM_on1 or TM_on2 of the external command signal TM which are applied to the address connection A600 of the integrated semiconductor memory.

The integrated semiconductor memory shown in FIG. 1 makes it possible to increase the frequency of the frequency signal RFS when testing the integrated semiconductor memory in comparison with the frequency of the frequency signal RFS during subsequent operation of the integrated semiconductor memory and to lengthen the intervals of time at which memory cells are refreshed in comparison with subsequent operation by a customer.

FIG. 2 shows a first embodiment of an integrated circuit for differently setting the frequency of the frequency signal RFS in the test mode in comparison with subsequent operation in a user's computer application (i.e., in a normal operating state). The temperature sensor circuit 300 is connected between an input connection E400 of the control circuit 400 and a supply connection V for applying a reference voltage VSS, for example a ground potential. The control circuit 400 has a resistor 410 which is connected in series with a resistor 430 between the input connection E400 of the control circuit 400 and a control connection S500 of the frequency generation unit 500. A controllable switch 450 having a control connection S450 for applying the test mode control signal TMS2 is connected in parallel with the resistor 430. If the controllable switch 450 is turned on, the resistor 430 can be bridged in a low-impedance manner.

Furthermore, a controllable switch 440 having a control connection S440 for applying the test mode control signal TMS1 is connected between the input connection E400 of the control circuit 400 and the control connection S500 of the frequency generation unit 500. Turning on the controllable switch 440 makes it possible to connect the input connection E400 to the control connection S500 with a lower impedance than is possible using the circuit comprising the resistor 410 and the parallel circuit comprising the resistor 430 and the controllable switch 450.

In addition, the control circuit 400 has a resistor 420 which is connected between the control connection S500 of the frequency generation unit and the supply connection V for applying the reference voltage VSS. The frequency generation unit 500 is likewise arranged between the control connection S500 and the supply connection V for applying the reference voltage VSS. It generates the frequency signal RFS at the output.

The method of operation of the circuit arrangement shown in FIG. 2 is described below. The integrated semiconductor memory is operated in an active operating state in which read and write accesses to memory cells of the memory cell array can be carried out. In order to operate the integrated semiconductor memory in the active operating state, a state of a command signal MS is first of all applied to a control connection S200c which signals the active operating state to the control unit 200. In the active operating state, data is read into the memory cells and is refreshed on the basis of a frequency of the refresh command signal MS which is applied to a control connection S200c. The memory cells to be selected for a write and read access are selected by applying an address signal to the address connection A600.

A corresponding change in the state of the command signal MS is then used to change the integrated semiconductor memory to a sleep mode (standby mode) in which write and read accesses are no longer carried out. The self-refresh mode of the memory is simultaneously turned on in the standby mode. Generation of the frequency signal RFS for testing the memory in the self-refresh mode is described below.

The temperature sensor 300 generates the evaluation voltage TS at the output on the basis of a chip temperature on the memory chip of the integrated semiconductor memory, the evaluation voltage being supplied to the control circuit 400. In the normal operating state of the integrated semiconductor memory, for example when operating the integrated semiconductor memory in a user's computer application, the state TM_off of the command signal TM is applied to the address connection. The control unit 200 then generates the test mode control signal TMS1 with a state which turns on the controllable switch 440. The control unit 200 also generates the test mode control signal TMS2 at the output in such a manner that the controllable switch 450 is turned off. In this case, the evaluation voltage TS is directly supplied to the control connection S500 of the frequency generation unit 500.

The frequency generation unit 500 is in the form of a voltage-controlled oscillator, for example. A frequency of the frequency signal RFS, at which the memory cells of the memory cell array 100 are refreshed, is thus generated on the basis of the chip temperature detected by the temperature sensor circuit 300. In this case, the frequency generation unit 500 is designed in such a manner that higher frequencies of the frequency signal RFS are generated at high chip temperatures than if low chip temperatures are detected.

In the test operating state of the integrated semiconductor memory, a state TM_on1 of the command signal TM or a state TM_on2 of the command signal TM is applied to the address connection A600. If the control unit 200 determines that a command signal TM having the characteristic bit sequence TM_on1 is applied to the address connection A600, the test mode control signals TMS1 and TMS2 are generated in such a manner that the controllable switch 440 is turned off and the controllable switch 450 is turned on. On account of the voltage drop across the resistor 410, the control connection S500 is thus driven by a voltage TS1 which is lower than the voltage TS.

On account of the fact that the control connection S500 of the voltage-controlled oscillator is driven with a lower control voltage, the frequency signal RFS is generated at a lower frequency. In this case, the resistors 410 and 420 can be dimensioned in such a manner that the frequency of the frequency signal RFS is, for example, ten percent lower than the frequency generated during operation by a user. This makes it possible to refresh the memory cells at a lower and thus more critical refresh frequency in the test operating state at the same chip temperature as in a normal operating state.

If the command signal TM with the state TM_on2 is applied to the address connection A600, the control circuit 200 generates the test mode control signals TMS1 and TMS2 at the output in such a manner that the controllable switch 440 and the controllable switch 450 are turned off. In this case, the full level of the voltage TS is no longer applied to the control connection S500 of the voltage-controlled oscillator but rather a level of a control voltage TS2 that is again reduced in comparison with the voltage TS and the voltage TS1. As a result of the level of the control voltage at the control connection S500, which level is again reduced, the voltage-controlled oscillator 500 generates the frequency signal RFS at a frequency which is again reduced in comparison with driving with the control voltage TS1. Suitably dimensioning the resistors 410, 420 and 430 makes it possible, for example, for the frequency signal RFS to be generated at a frequency that is reduced by, for example, twenty percent in comparison with driving with the voltage TS. This makes it possible to again reduce the refresh frequencies for refreshing the memory cells of the memory cell array 100 in the test operating state of the integrated semiconductor memory.

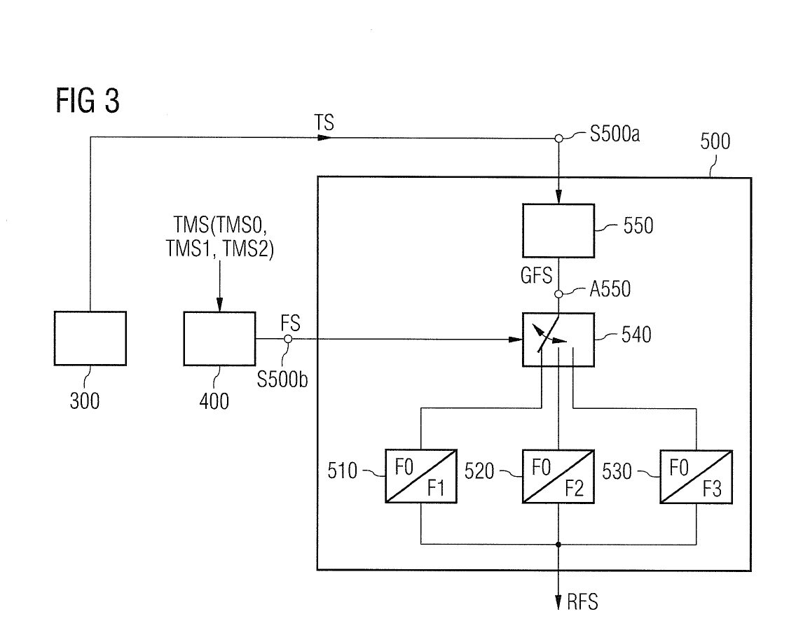

FIG. 4A shows the dependence of the refresh intervals ΔI on the chip temperature T when operating the integrated semiconductor memory in the self-refresh mode of the normal operating state, in which the address connection A600 is driven by the state TM_off of the command signal TM, and in the self-refresh mode of the test operating state, in which the address connection A600 is driven by the states TM_on1 and TM_on2 of the command signal. FIG. 4B shows the dependence of the refresh frequency F on the chip temperature detected by the temperature sensor circuit during operation of the semiconductor memory in the abovementioned operating states. On account of the linear current/voltage dependence across the resistors 410, 420 and 430, the circuit arrangement shown in FIG. 2 can be used to generate a linear dependence of the refresh intervals and/or the refresh frequencies on the detected chip temperature.

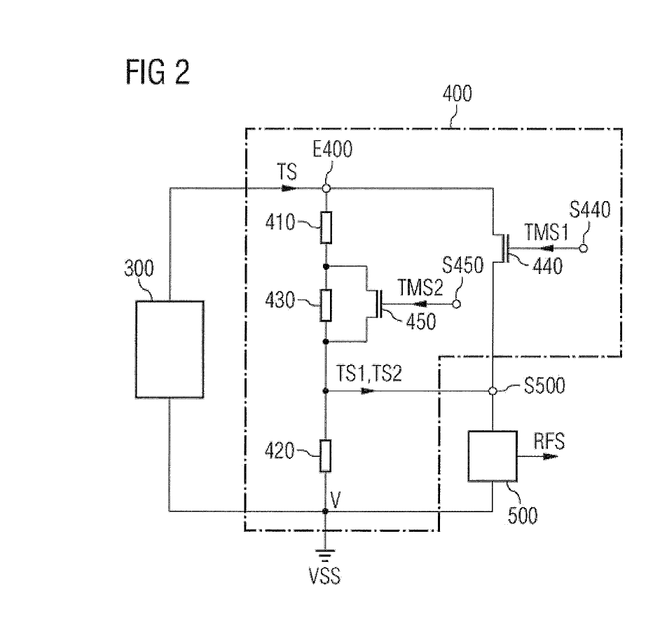

FIG. 3 shows another embodiment and connection of the temperature sensor circuit 300, the control circuit 400 and the frequency generation unit 500 for generating the frequency signal RFS. The temperature sensor circuit 300 generates the temperature evaluation signal TS at the output on the basis of the detected chip temperature, the temperature evaluation signal being supplied to a control connection S500a of the frequency generation unit 500. The control circuit 400 is driven by the control unit 200 using the test mode control signals TMS0, TMS1 or TMS2. It generates a control signal FS at a control connection S500b on the basis of the test mode control signals.

The frequency generation unit 500 comprises a frequency generator circuit 550 which generates a fundamental frequency signal GFS at a fundamental frequency F0 on the basis of the detected chip temperature or on the basis of a level of the temperature evaluation signal TS, the fundamental frequency signal being supplied to an output connection A550 of the frequency generator circuit 550. The frequency generator circuit 550 is in the form of a voltage-controlled oscillator, for example. A controllable circuit unit 540 is connected to the output connection A550. The output of the controllable circuit unit 540 is connected to a frequency divider circuit 510, a frequency divider circuit 520 and a frequency divider circuit 530. The controllable circuit unit 540 can be switched on the basis of the control signal FS in such a manner that the fundamental frequency signal GFS is supplied to the frequency divider circuit 510, the frequency divider circuit 520 or the frequency divider circuit 530. The frequency divider circuits have different divider ratios. In one exemplary embodiment, the divider ratios are selected such that the frequency of the frequency signal RFS generated by the frequency divider circuit 520 is ten percent lower than the frequency F1 generated by the frequency divider circuit 510 and the frequency F3 generated by the frequency divider circuit 520 is twenty percent lower than the frequency F1 generated by the frequency divider circuit 510.

The method of operation of the circuit arrangement shown in FIG. 3 is described in more detail below. As described in the embodiment in FIG. 2, the integrated semiconductor memory is operated in an active operating state in which read and write accesses to memory cells of the memory cell array 100 are carried out. To this end, the control connection S200c is driven using a first state of the control signal MS. The contents of the memory cells are refreshed when the control connection S200b is driven using the refresh command signal RKS which is generated by a memory controller, for example. A change in the state of the control signal MS causes the integrated semiconductor memory to be operated in the standby mode. In the standby mode, the refresh frequency is internally generated by the semiconductor memory using the frequency generation unit 500.

In a standby mode outside the test mode, the command signal TM with the state TM_off is applied to the address connection A600. In this case, the control unit 200 generates, at the output, the test mode control signal TMS0 which is supplied to the control circuit 400. The control circuit 400 then drives the controllable circuit unit 540 using a control signal FS in such a manner that the output connection A550 of the frequency generator circuit is connected to the frequency divider circuit 510. The frequency divider circuit 510 uses the fundamental frequency F0 which has been supplied to it to generate the frequency signal RFS at a frequency F1. In this case, the memory cells of the memory cell array are refreshed at the refresh frequency F1.

If, in contrast, the integrated semiconductor memory is operated in the self-refresh mode and a command signal TM with the state TM_on1 is applied to the address connection A600, the control unit 200 generates the test mode control signal TMS1. The control circuit 400 then drives the controllable circuit unit 540 using the control signal FS such that the output connection A550 of the frequency generator circuit 550 is connected to the frequency divider circuit 520. A frequency signal RFS at the frequency F2 is thus generated from the fundamental frequency F0.

If the address connection A600 is driven in the self-refresh mode using the state TM_on2 of the command signal TM, the control unit 200 generates, at the output, the test mode control signal TMS2 which is used to drive the control circuit 400. The control circuit 400 then drives the controllable circuit unit 540 using the control signal FS such that the output connection A550 is connected to the frequency divider circuit 530. The frequency signal RFS at a frequency F3 is thus generated from the fundamental frequency F0.

The memory cells of the integrated semiconductor memory can thus be operated in the self-refresh mode while testing the semiconductor memory at the refresh frequencies F2 and F3 which are lower than the refresh frequency F1, thus making it possible to test the behavior of the memory at critical refresh frequencies.

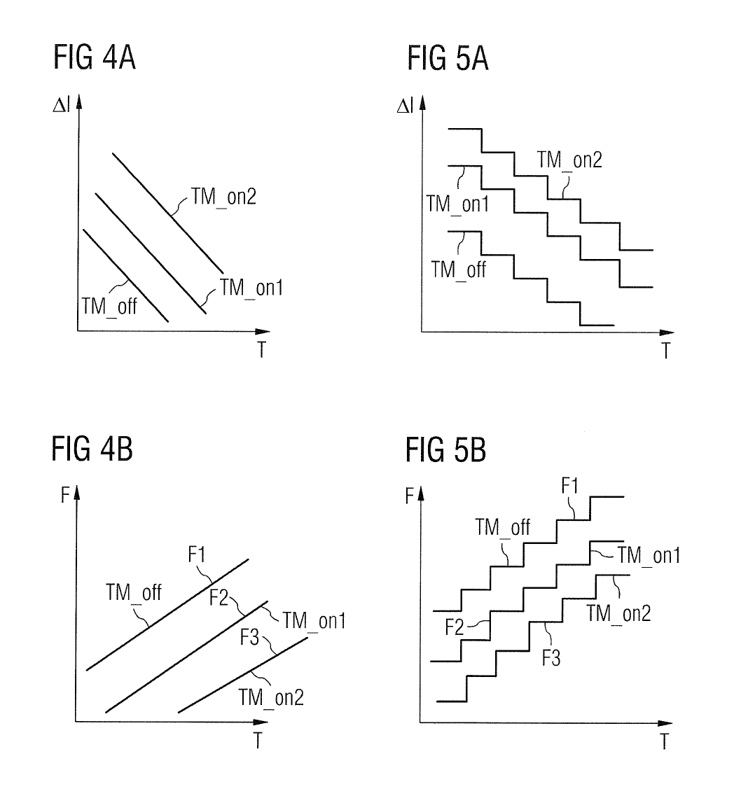

FIGS. 4 and 5 show dependences of the refresh intervals ΔI and the refresh frequencies F on the detected chip temperature T, which dependences can be generated using the circuit arrangement shown in FIG. 3. In addition to the linear relationship (shown in FIGS. 4A and 4B) between the refresh intervals/refresh frequencies and the detected chip temperature T, it is possible, in particular with the embodiment shown in FIG. 3, to generate the discrete refresh intervals/refresh frequencies shown in FIGS. 5A and 5B. To this end, the voltage-controlled oscillator 550 is designed in such a manner that it changes the generated fundamental frequency F0 in a stepwise manner on the basis of the chip temperature.

After the refresh frequencies have been reduced or the refresh intervals have been lengthened in the test operating state, the semiconductor memory is changed over to the active operating state again. In the active operating state, the contents of the memory cells are read out and are compared with the data which were read into the memory cells before operation in the test operating state. If the data values correspond, the semiconductor memory device has successfully passed the test.

What is claimed is:

1. An integrated semiconductor memory with refreshing of memory cells, comprising:
a temperature sensor to detect a chip temperature of the integrated semiconductor memory;
a frequency generation unit to generate a frequency signal; and
a memory cell to store a data item, the stored data item being refreshed at the frequency of the frequency signal;
wherein, in response to the integrated semiconductor memory receiving a command signal in a first state, the frequency generation unit generates the frequency signal at a first frequency that is a function of the chip temperature and, in response to the integrated semiconductor memory receiving the command signal in a second state, the frequency generation unit generates the frequency signal at a second frequency that is a function of the chip temperature, the second frequency being different from the first frequency.

2. The integrated semiconductor memory as claimed in claim 1, wherein the temperature sensor is configured to generate an evaluation signal based on the chip temperature.

3. The integrated semiconductor memory as claimed in claim 1, further comprising a control circuit to generate a control signal that controls the frequency generation unit to set the frequency of the frequency signal.

4. The integrated semiconductor memory as claimed in claim 3, wherein:
the temperature sensor generates an evaluation voltage as an evaluation signal;
the control circuit generates a control voltage as the control signal in response to the evaluation voltage, the control circuit supplying either the evaluation voltage or a modified evaluation voltage as the control voltage based on a state of the command signal; and
the frequency generation unit generates the frequency of the frequency signal based on the control voltage.

5. The integrated semiconductor memory as claimed in claim 1, wherein the frequency generation unit comprises a voltage-controlled oscillator.

6. An integrated semiconductor memory with refreshing of memory cells, the integrated semiconductor memory being operable in a test operating mode and in a normal operating mode and comprising:
a temperature sensor to detect a chip temperature of the integrated semiconductor memory;
a frequency generation unit to generate a frequency signal at a frequency dependent on the chip temperature; and
a memory cell to store a data item, the stored data item being refreshed at the frequency of the frequency signal;
wherein, at a given chip temperature, the frequency generation unit generates the frequency signal at a first frequency when operated in the normal operating mode and at a second, different frequency when operated in the test operating mode.

7. The integrated semiconductor memory as claimed in claim 6, wherein the temperature sensor is configured to generate an evaluation signal based on the chip temperature.

8. The integrated semiconductor memory as claimed in claim 6, further comprising a control circuit configured to generate a control signal that controls the frequency generation unit to set the frequency of the frequency signal.

9. The integrated semiconductor memory as claimed in claim 8, wherein:
the temperature sensor generates an evaluation voltage as an evaluation signal;
the control circuit generates a control voltage as the control signal in response to the evaluation voltage, the control circuit supplying either the evaluation voltage or a modified evaluation voltage as the control voltage based on a state of the command signal; and
the frequency generation unit generates the frequency of the frequency signal based on the control voltage.

10. The integrated semiconductor memory as claimed in claim 6, wherein the frequency generation unit comprises a voltage-controlled oscillator.

11. An integrated semiconductor memory with refreshing of memory cells, comprising:
a temperature sensor to detect a chip temperature of the integrated semiconductor memory, the temperature sensor generating an evaluation voltage based on the detected chip temperature;
a control circuit to generate a control voltage based on the evaluation voltage, the control circuit being capable of modifying the evaluation voltage to produce a modified evaluation voltage, wherein, based on a received command signal, the control circuit selects as the control voltage either the evaluation voltage or the modified evaluation voltage;
a frequency generation unit to generate a frequency signal based on the control voltage; and
a memory cell to store a data item, the stored data item being refreshed at the frequency of the frequency signal.

12. The integrated semiconductor memory as claimed in claim 11, wherein:
the control circuit comprises an input connection for receiving the evaluation voltage, an output connection for supplying the control voltage to the frequency generation unit, a first controllable switch, a first resistor, and a second resistor;
the temperature sensor is connected between the input connection of the control circuit and a reference voltage node;
the first controllable switch and the first resistor are connected in parallel between the input connection of the control circuit and the output connection of the control circuit; and
the frequency generation unit is connected in parallel with the second resistor between the output connection of the control circuit and the reference voltage node.

13. The integrated semiconductor memory as claimed in claim 12, wherein the first controllable switch is operable to bridge the first resistor in a low-impedance manner.

14. The integrated semiconductor memory as claimed in claim 12, wherein the control circuit further comprises a third resistor connected in series with the first resistor and a second controllable switch operable to bridge the third resistor in a low-impedance manner.

15. The integrated semiconductor memory as claimed in claim 12, wherein the first and second controllable switches comprise transistors.

16. An integrated semiconductor memory with refreshing of memory cells, comprising:
a temperature sensor to detect a chip temperature of the integrated semiconductor memory;
a frequency generation unit to generate a frequency signal, the frequency being dependent on the chip temperature detected by the temperature sensor; and
a memory cell to store a data item, the stored data item being refreshed at the frequency of the frequency signal;
wherein, at a given chip temperature, the frequency generation unit generates the frequency signal at a first frequency in response to the integrated semiconductor memory receiving a command signal in a first state and generates the frequency signal at a second frequency that is less than the first frequency in response to the integrated semiconductor memory receiving the command signal in a second state.

17. The integrated semiconductor memory as claimed in claim 16, wherein:
the temperature sensor is configured to generate an evaluation signal based on the detected chip temperature;
the frequency generation unit comprises an oscillator circuit configured to generate a fundamental frequency signal at a fundamental frequency in response to the evaluation signal, a first frequency divider circuit having a first divider ratio, and a second frequency divider circuit having a second divider ratio;
the first frequency divider circuit generates the first frequency from the fundamental frequency signal based on the first divider ratio; and
the second frequency divider circuit generates the second frequency from the fundamental frequency signal based on the second divider ratio.

18. The integrated semiconductor memory as claimed in claim 17, further comprising a controllable circuit unit connected between the oscillator circuit and the first and second frequency divider circuits, the controllable circuit unit being configured to supply the fundamental frequency signal to the first frequency divider circuit or to the second frequency divider circuit based on the state of the command signal.

19. The integrated semiconductor memory as claimed in claim 17, further comprising a third frequency divider circuit coupled to the oscillator circuit and being configured to generate the frequency signal at a third frequency which is less than the second frequency in response to a third state of the command signal.

20. The integrated semiconductor memory as claimed in claim 19, wherein the controllable circuit unit is connected between the oscillator circuit and the third frequency divider circuit and supplies the fundamental frequency signal to one of the first, second, and third frequency divider circuits based on the state of the command signal.

21. The integrated semiconductor memory as claimed in claims 17, wherein the oscillator circuit is adapted to generate the fundamental frequency of the fundamental frequency signal based on the evaluation signal.

22. The integrated semiconductor memory as claimed in claim 17, wherein:
the oscillator circuit generates the fundamental frequency signal at a first fundamental frequency in response to the chip temperature being in a range between two chip temperatures; and
the oscillator circuit generates the fundamental frequency signal at a second fundamental frequency in response to the chip temperature being in another range between two other chip temperatures.

23. A memory device operable in a normal operating mode and in a test mode, the memory device comprising:
a plurality of memory cells for storing data; and
a frequency generation unit configured to generate a frequency signal for performing a self-refresh of the memory cells, wherein, in the normal operating mode, the frequency generation unit is configured to generate the frequency signal at a first frequency that is function of a detected temperature of the memory device and, in the test mode, the frequency generation unit is configured to generate the frequency signal at a second frequency that is a function of the detected temperature of the memory device, the second frequency being different from the first frequency at a given temperature.

24. A method for testing an integrated semiconductor memory comprising memory cells for storing data and a frequency generation unit for generating a frequency signal at a frequency based on a chip temperature of the integrated semiconductor memory and a state of a command signal, the data being refreshed at the frequency of the frequency signal to retain a data item stored in one of the memory cells, the method comprising:
detecting a first chip temperature of the integrated semiconductor memory;
generating the frequency signal with a first frequency as a function of the first chip temperature in response to the command signal being in a first state; and
generating the frequency signal with a second frequency as a function of the first chip temperature in response to the command signal being a second state, the second frequency being less than the first frequency.

25. The method as claimed in claim 24, further comprising:
changing the chip temperature of the integrated semiconductor memory by heating or cooling;
detecting a second chip temperature that differs from the first chip temperature;
generating the frequency signal at the second frequency at the detected second chip temperature in response to the second chip temperature being between a first temperature value and a second temperature value of the chip temperature; and
generating the frequency signal at a changed second frequency in response to the second chip temperature being greater than the first temperature value or less than the second temperature value of the chip temperature.

26. The method as claimed in claim 24, further comprising:
changing the chip temperature of the integrated semiconductor memory by heating or cooling;
detecting a second chip temperature that differs from the first chip temperature; and
generating the frequency signal at a changed second frequency, the changed second frequency being greater than the second frequency in response to the second chip temperature being greater than the first chip temperature, and being less than the second frequency in response to the second chip temperature being less than the first chip temperature.
